(19) United States
(12) Patent Application Publication
(10) Pub. No.: US 2018/0233286 A1
(43) Pub. Date: Aug. 16, 2018

(54) CAPACITOR COMPONENT AND METHOD OF MANUFACTURING THE SAME

(71) Applicant: SAMSUNG ELECTRO-MECHANICS CO., LTD., Suwon-s (KR)

(72) Inventors: Il Hwan YU, Suwon-si (KR); Ki Pyo HONG, Suwon-si (KR); Jong Ho LEE, Suwon-si (KR)

(73) Assignee: SAMSUNG ELECTRO-MECHANICS CO., LTD.

(21) Appl. No.: 15/696,765

(22) Filed: Sep. 6, 2017

(30) Foreign Application Priority Data
Feb. 15, 2017 (KR) 10-2017-0020720

(51) Int. Cl. H01G 4/232; H01G 4/12; H01G 9/07; H01G 9/048; H01G 4/005; H01G 4/30; H01G 4/236; H01G 4/33; H01L 49/02; H05K 1/16

(52) U.S. Cl. CPC H01G 4/232; H01G 4/12; H01G 9/07; H01G 9/048; H01G 4/005; H05K 2201/09763; H01G 4/236; H01G 4/33; H01L 28/40; H05K 1/162; H01G 4/30

(57) ABSTRACT

A capacitor component includes a body including a structure in which a plurality of dielectric layers are stacked and a plurality of internal electrodes stacked with respective dielectric layers interposed therebetween, reinforcing layers formed on surfaces of the body to which the internal electrodes are exposed to thus cover portions of the internal electrodes, and external electrodes connected to the internal electrodes while covering the internal electrodes and the reinforcing layers.

### CROSS-REFERENCE TO RELATED APPLICATION(S)

This application claims priority from Korean Patent Application No. 10-2017-0020720 filed on Feb. 15, 2017, in the Korean Intellectual Property Office (KIPO), the disclosure of which is incorporated herein by reference in its entirety.

### BACKGROUND

### 1. Field

The present disclosure relates to a capacitor component and a method of manufacturing the same.

### 2. Description of Related Art

A multilayer ceramic capacitor, a capacitor component, is a chip-type condenser mounted on the printed circuit boards (PCBs) of several electronic products, such as an image display apparatuses (a liquid crystal display (LCD), a plasma display panel (PDP), or the like), a computer, a smartphone, a cellular phone, and the like, for charging or discharging electricity therein or therefrom.

Such a multilayer ceramic capacitor (MLCC) may be used as a component of various electronic apparatuses since it is relatively small, a high capacitance can be obtained, and can be connected on the PCB and to other components with relative ease. Recently, multilayer ceramic capacitors used in a mobile device, an automobile, or the like, are required to have a high mechanical strength. For example, such multilayer ceramic capacitors used in the mobile device, an automobile, or the like, should be able to withstand conditions such as external repeated vibrations, impacts, harsh temperatures and humidity, and the like. In an MLCC used in the related art, external electrodes are vulnerable to the permeation of moisture, a plating solution, or the like.

### SUMMARY

An aspect of the present disclosure may provide a capacitor component in which sealing characteristics of external electrodes may be improved by reducing permeation of moisture or plating solution. An aspect of the present disclosure may also provide a method of manufacturing a capacitor component capable of efficiently manufacturing the capacitor component.

According to an aspect of the present disclosure, a capacitor component may include: a body including a stacked plurality of dielectric layers and a stacked plurality of internal electrodes with respective dielectric layers interposed therebetween, reinforcing layers on surfaces of the body on which the internal electrodes are exposed, and thereby the reinforcing layers covering portions of the internal electrodes, and external electrodes connected to the internal electrodes and covering the internal electrodes and the reinforcing layers.

A pair of reinforcing layers may be on each surface of the body on which the internal electrodes are exposed.

The pair of reinforcing layers are on edges of the surfaces of the body and the pair of reinforcing layers are spaced apart from each other.

The pair of reinforcing layers may cover distal ends of the internal electrodes.

At least one reinforcing layer of the pair of reinforcing layers includes a portion having a width different from rest of the at least one reinforcing layer.

A width of a central portion of the at least one reinforcing layer may be smaller than rest of the at least one reinforcing layer in the direction in which the plurality of dielectric layers are stacked.

Each reinforcing layer of the pair of reinforcing layers has an inner edge that is curved.

The reinforcing layers may cover portions of the internal electrodes and expose remaining portions of the internal electrodes.

The external electrodes may be connected to the internal electrodes via the exposed portion thereof.

The reinforcing layer may include an electrical insulating material.

The reinforcing layer and the dielectric layer may include a same material.

The reinforcing layer and the dielectric layer may include a sintered ceramic.

At least one external electrode may have a multilayer structure.

The external electrode may include a first layer that is a sintered electrode and a second layer that covers the first layer and is a plating electrode.

According to another aspect of the present disclosure, a method of manufacturing a capacitor component may include: forming a body by alternately stacking a plurality of dielectric layers and internal electrodes, forming reinforcing layers on surfaces of the body from which the internal electrodes are exposed, and thereby covering portions of the internal electrodes, and forming external electrodes connected to the internal electrodes and covering the reinforcing layers.

The reinforcing layers may be formed by transferring the reinforcing layer to the body.

The method may further include co-sintering the body and the reinforcing layers.

### BRIEF DESCRIPTION OF DRAWINGS

The accompanying drawings, which are included to provide further understanding and are incorporated in and constitute a part of this specification, illustrate disclosed embodiments and together with the description serve to explain the principles of the disclosed embodiments. In the drawings:

FIG. 1 is a perspective view of a capacitor component according to an exemplary embodiment in the present disclosure.

FIG. 2 is a perspective view illustrating a body, internal electrodes, and reinforcing layers in the capacitor component of FIG. 1.

FIG. 3 is a cross-sectional view of the capacitor component of FIG. 1 taken in the I-I′ plane.

FIG. 4 is a cross-sectional view of the capacitor component of FIG. 1 taken in the II-II′ plane.

FIGS. 5 and 6 illustrate side views of different configurations of reinforcing layers, according to disclosed embodiments.

FIGS. 7A through 9 illustrate a method of manufacturing a capacitor component according to an exemplary embodiment in the present disclosure.

### DETAILED DESCRIPTION

Hereinafter, exemplary embodiments of the present disclosure will now be described in detail with reference to the accompanying drawings.

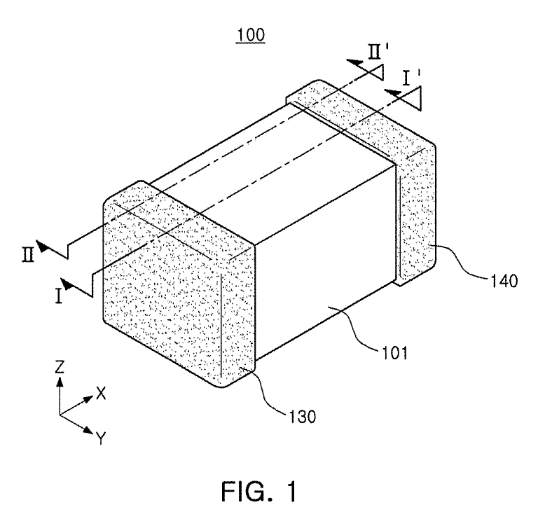

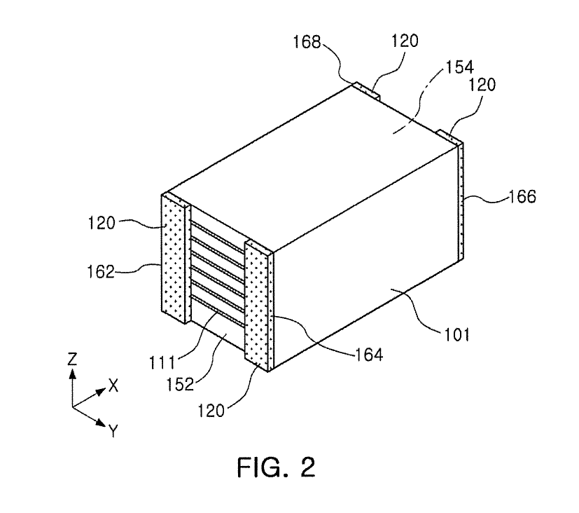

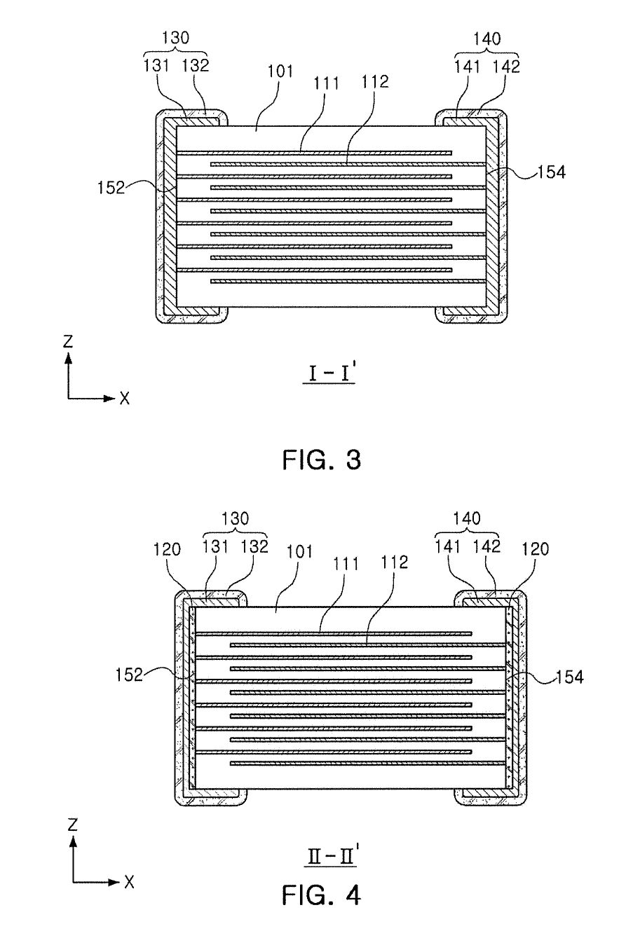

FIG. 1 is a perspective view of a capacitor component 100 according to an exemplary embodiment in the present disclosure. FIG. 2 is a perspective view illustrating a body, internal electrodes, and reinforcing layers in the capacitor component 100 of FIG. 1. FIG. 3 is a cross-sectional view of the capacitor component 100 of FIG. 1 taken in the I-I′ plane. FIG. 4 is a cross-sectional view of the capacitor component 100 of FIG. 1 taken in the II-II′ plane.

Referring to FIGS. 1 through 4, the capacitor component 100 (FIG. 1) may include a body 101 having first and second internal electrodes 111 and 112 (FIGS. 3 and 4) disposed therein, reinforcing layers 120, and first and second external electrodes 130 and 140. The reinforcing layers 120 cover surfaces 152 and 154 (FIGS. 3 and 4) of the body 101 from which the first and second internal electrodes 111 and 112 are exposed and the reinforcing layers 120 may be configured to reduce permeation of moisture, a plating solution, or the like, from the edges (or locations adjacent thereto) of the capacitor component 100. Because of the reinforcing layers 120, moisture resistance of the capacitor component 100 may be effectively improved without requiring substantial changes to shapes of the first and second internal electrodes 111 and 112.

The body 101 may include a multilayer structure in which a plurality of dielectric layers are stacked (for example, in the Z-direction), and the first and second internal electrodes 111 and 112 alternately disposed with respective dielectric layers interposed therebetween. As illustrated in FIG. 2, the body 101 may have a hexahedral shape or a similar shape, and include a first surface 152 and a second surface 154 opposing each other (for example, in the X-direction in FIGS. 3 and 4).

The dielectric layers included in the body 101 may be or include a dielectric material such as a ceramic material, for example, a barium titanate (BaTiO₃) -based ceramic powder, or the like. An example of the barium titanate (BaTiO₃) based ceramic powder may include (Ba₁₋ₓCaₓ)TiO₃, Ba(Ti_{1-y}Ca_{y})O₃, (Ba₁₋ₓCaₓ) (Ti_{1-y}Zr_{y})O₃, Ba(Ti_{1-y}Zr_{y})O₃, a combination thereof, and the like. Calcium (Ca), zirconium (Zr), a combination thereof, and the like may be partially dissolved in BaTiO₃. However, other types of ceramic powders may be used, without departing from the scope of the disclosure.

The body 101 may be divided into an active region including the capacitor portion of the capacitor component 100, and cover regions positioned on upper and lower surfaces (for example, in the Z-direction) of the active region. For example, referring to FIG. 1, the active region may include the capacitor portion formed by the first and second internal electrodes 111 and 112, and the cover regions may be disposed on the upper and lower surfaces of the active region. In this case, the cover regions may prevent damage to the first and second internal electrodes 111 and 112 due to physical or chemical stress, and may be formed of the same material as that of the dielectric layers of the active region and have the same configuration as that of the dielectric layers of the active region except that they do not include the internal electrodes 111 and 112. In this case, the cover regions may be obtained together by stacking and then sintering green sheets. The cover regions may be implemented by stacking one or more green sheets on the upper and lower surfaces of the active region and then sintered the stacked green sheets.

The first and second internal electrodes 111 and 112 may be alternately disposed to face each other with respective dielectric layers of the body 101 interposed therebetween, and may be exposed from both end surfaces 152 and 154 of the body 101, respectively. Here, the first and second internal electrodes 111 and 112 may be electrically separated from each other by respective dielectric layers disposed therebetween. A material forming respective first and second internal electrodes 111 and 112 is not limited to any particular material, and may be or include a conductive paste formed of one or more of, a noble metal material such as palladium (Pd), a palladium-silver (Pd—Ag) alloy, nickel (Ni), copper (Cu), a combination thereof and the like. The conductive paste may be printed using a variety of methods including, but not limited to, a screen printing method, a gravure printing method, or the like. In addition, thicknesses of the first and second internal electrodes 111 and 112 may be, for example, 0.1 to 5 μm or 0.1 to 2.5 μm, but are not limited thereto.

The reinforcing layers 120 may be formed on the surfaces 152 and 154 of the body 101 from which the internal electrodes 111 and 112 are exposed and may thus cover portions of the internal electrodes 111 and 112. The reinforcing layers 120 may protect the body 101 and the internal electrodes 111 and 112 from moisture, the plating solution, or the like, to which the body 101 and the internal electrodes 111 and 112 may be exposed. In an example, and as illustrated in FIG. 2, the reinforcing layers 120 may be formed in pairs on the surfaces 152 and 154. In more detail, each reinforcing layer 120 of the pair of reinforcing layers 120 may be disposed on (or proximate) the edges 162, 164, 166, and 168 (FIG. 2) of the surfaces 152 and 154 and are spaced apart from each other such that portions of the internal electrodes 111 and 112 are exposed between the pair of reinforcing layers 120. As illustrated in FIG. 2, the capacitor component 100 may include four reinforcing layers 120 may be formed. However, the number of reinforcing layers 120 may increase or decrease depending on the application, design preferences, and the like.

As described above, the reinforcing layers 120 may protect the internal electrodes 111 and 112, and each reinforcing layer 120 may extend in the thickness direction (Z-direction) and the width direction (Y-direction) on the respective surfaces 152 and 154, thereby covering distal ends of the internal electrodes 111 and 112.

As illustrated, the reinforcing layers 120 may cover only portions of the internal electrodes 111 and 112 and expose the remaining portions of the internal electrodes 111 and 112, and the external electrodes 130 and 140 may be disposed on the surfaces 152 and 154 and may be electrically connected to exposed regions of the internal electrodes 111 and 112, respectively.

The reinforcing layers 120 may be formed of an electrical insulating material, a material that may protect the internal electrodes 111 and 112, and the like. As an example, the reinforcing layers 120 may be formed of the same material as that of the dielectric layers constituting the body 101, and the reinforcing layers 120 and the dielectric layers may be formed of a sintered ceramic. In this case, as described below, the reinforcing layers 120 and the dielectric layer may be formed by co-sintering.

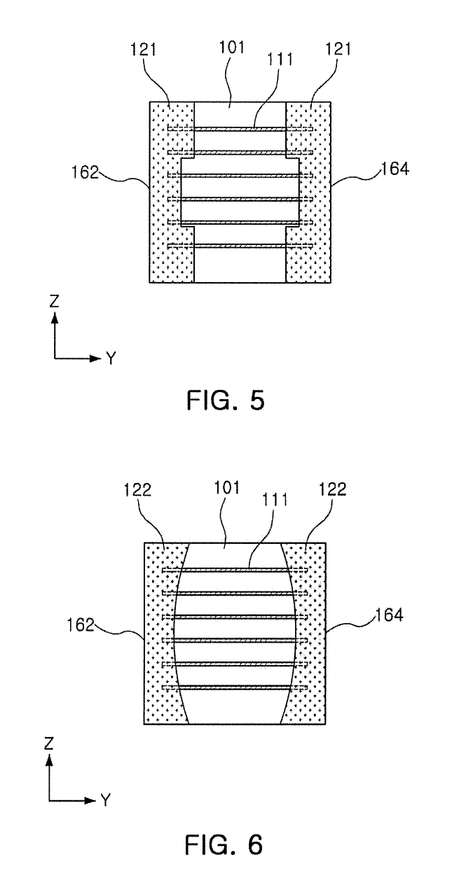

As discussed below with reference to FIGS. 5 and 6, the shapes of the reinforcing layers 120 may be modified in consideration of moisture resistance reliability, electrical connectivity, and the like. FIGS. 5 and 6 are side views illustrating different configurations of the reinforcing layers 121 and 122, according to disclosed embodiments. In an example, the reinforcing layers 120 may be replaced with the reinforcing layers 121 and 122. Although FIGS. 5 and 6 illustrate the reinforcing layers 121 and 122 on the edges 162 and 164, it will be understood that the reinforcing layers 121 and 122 are also on the edges 166 and 168 (hidden from view in FIGS. 5 and 6).

As illustrated in FIGS. 5 and 6, the reinforcing layers 121 and 122 may have regions having different widths (in the Y-direction). As illustrated, a central portion of each reinforcing layer 121 and 122 in the stacking direction (Z-direction) may have a width smaller than the rest of the reinforcing layers 121 and 122. Generally, permeation of moisture, a plating solution, and the like, occurs at or adjacent the edge regions of the body 101. Thus, the relatively thicker outer portions of the reinforcing layers 121 and 122, may provide a sufficiently secure electrical connectivity between internal electrodes 111 and 112 and external electrodes 130 and 140 and reliable moisture resistance.

As illustrated, the inner edges (for example, edges proximate the exposed internal electrodes 111 and 112) of the pair of reinforcing layers 121 may have a stepped structure as illustrated in FIG. 5 or the inner edges of the pair of reinforcing layers 122 may be curved, as illustrated in FIG. 6.

Referring to FIGS. 2 and 4, the first and second external electrodes 130 and 140 may be formed on the outer surfaces of the body 101, and may be electrically connected to the first and second internal electrodes 111 and 112, respectively. The first and second external electrodes 130 and 140 may be connected to the first and second internal electrodes 111 and 112, respectively, while covering (e.g., entirely) the internal electrodes 111 and 112 and the reinforcing layers 120. A structure in which the capacitor component 100 includes two external electrodes 130 and 140 is described in the present exemplary embodiment, but the number of external electrodes 130 and 140 may change depending on the design and application. Further, the number of external electrodes 130 and 140 may vary depending on the shapes of the internal electrodes 111 and 112.

The first and second external electrodes 130 and 140 may have multilayer structures, respectively. For example, the first and second external electrodes 130 and 140 may include first layers 131 and 141 and second layers 132 and 142, respectively. Here, the first layers 131 and 141 may be formed of sintered electrodes obtained by sintering a conductive paste, and the second layers 132 and 142 may cover the first layers and may include one or more plating layers. The permeation of plating solution into the body 101 in a process of forming the plating layers may be minimized by the reinforcing layers 120. In addition, the first and second external electrodes 130 and 140 may include other additional layers, in addition to the first layers 131 and 141 and the second layers 132 and 142. For example, the first and second external electrodes 130 and 140 may include conductive resin electrodes disposed between the first layers 131 and 141 and the second layers 132 and 142 to alleviate mechanical impacts, or the like.

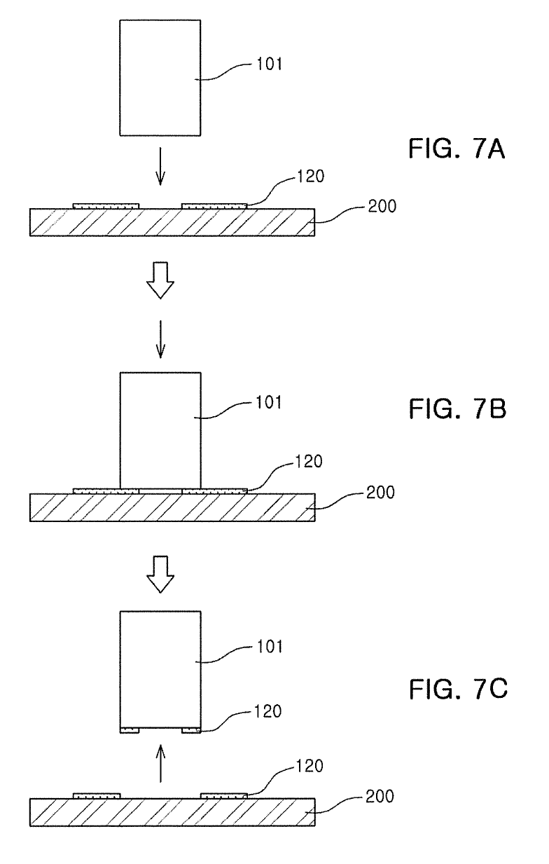

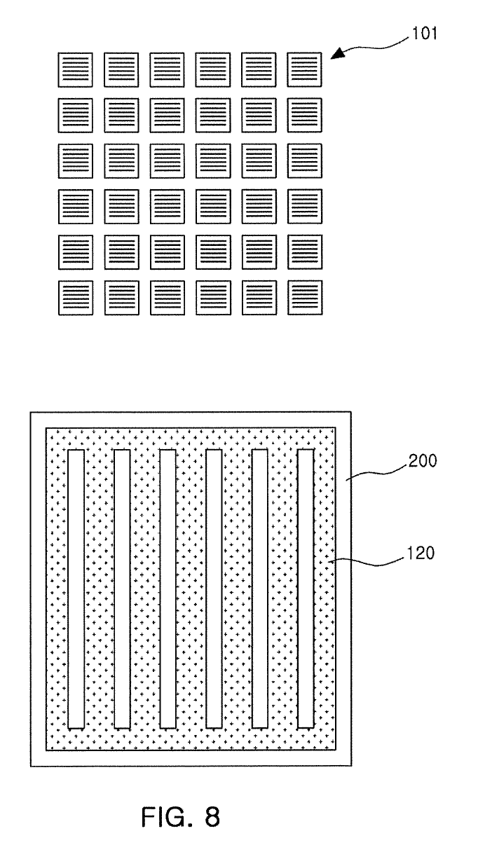

An example of a method of manufacturing the capacitor component having the structure described above will be described with reference to FIGS. 7A through 9. The structure of the capacitor component may be more clearly understood through a description of the method of manufacturing the capacitor component.

In a process of manufacturing the capacitor component, the reinforcing layer 120 may be first transferred to the surface of the body 101, as in a form illustrated in FIGS. 7A-7C. Here, the body 101 may be formed by alternately stacking the plurality of dielectric layers and the first and second internal electrodes 111 and 112. For example, a manner of applying a conductive paste for forming an internal electrode to ceramic green sheets and stacking the ceramic green sheets to which the conductive paste is applied may be used. The reinforcing layers 120 may be formed on the surfaces 152 and 154 of the body 101 to which the first and second internal electrodes 111 and 112 are exposed.

In a process of transferring the reinforcing layer 120, the reinforcing layer 120 having a sheet form may be prepared on a supporting stand 200 (FIG. 8), and the body 101 may be compressed with the reinforcing layer 120, such that a portion of the reinforcing layer 120 may be attached to the surface of the body 101. The reinforcing layer 120 transferred to the body 101 may be formed of the same ceramic green sheet as the ceramic green sheet used for manufacturing the body 101, and may include components such as a binder, an organic solvent, and the like, in a state before being sintered. However, an adhesive property of the reinforcing layers 120 before being sintered may be improved so that the reinforcing layer 120 is properly transferred to the body 101. To this end, before being sintered, the reinforcing layers 120 may include a relatively larger amount of organic material, such as a binder, or the like, than that of the body 101.

After the reinforcing layer 120 is formed on one surface of the body 101, the same process may be applied to the other surface of the body 101 to form the reinforcing layer 120 on the other surface of the body 101. Then, the body 101 and the reinforcing layer 120 may be fired or may be co-fired. Then, the external electrodes 130 and 140 connected to the internal electrodes 111 and 112, respectively, may be formed to obtain the capacitor component 100 having the structure described above.

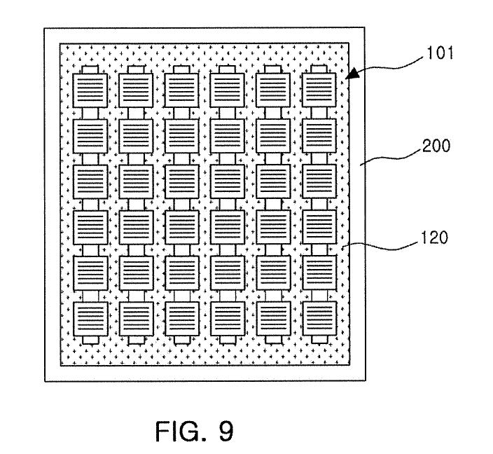

Meanwhile, the abovementioned transferring process may be simultaneously performed on a plurality of bodies 101 in a form illustrated in FIGS. 8 and 9 to improve process efficiency. FIG. 8 illustrates the plurality of bodies 101 are aligned with one another and the reinforcing layers 120 formed in an integral structure so as to correspond to the plurality of bodies 101, while FIG. 9 illustrates the plurality of bodies 101 and the reinforcing layers 120 bonded to each other.

As set forth above, according to the exemplary embodiment in the present disclosure, the capacitor component in which sealing characteristics of the external electrodes may be improved to reduce a permeation of moisture or plating solution may be obtained. In addition, the method of manufacturing a capacitor component capable of efficiently manufacturing the capacitor component may be obtained.

While exemplary embodiments have been shown and described above, it will be apparent to those skilled in the art that modifications and variations could be made without departing from the scope of the present disclosure as defined by the appended claims.

What is claimed is:

1. A capacitor component comprising:
a body including a stacked plurality of dielectric layers and a stacked plurality of internal electrodes with respective dielectric layers interposed therebetween;
reinforcing layers on surfaces of the body on which the internal electrodes are exposed, and thereby the reinforcing layers covering portions of the internal electrodes; and
external electrodes connected to the internal electrodes and covering the internal electrodes and the reinforcing layers.

2. The capacitor component of claim 1, wherein a pair of reinforcing layers are on each surface of the body on which the internal electrodes are exposed.

3. The capacitor component of claim 2, wherein the pair of reinforcing layers are on edges of the surfaces of the body and the pair of reinforcing layers are spaced apart from each other.

4. The capacitor component of claim 2, wherein the pair of reinforcing layers covers distal ends of the internal electrodes.

5. The capacitor component of claim 4, wherein at least one reinforcing layer of the pair of reinforcing layers includes a portion having a width different from rest of the at least one reinforcing layer.

6. The capacitor component of claim 5, wherein a width of a central portion of the at least one reinforcing layer is smaller than rest of the at least one reinforcing layer.

7. The capacitor component of claim 5, wherein each reinforcing layer of the pair of reinforcing layers has an inner edge that is curved.

8. The capacitor component of claim 1, wherein the reinforcing layers cover portions of the internal electrodes and expose remaining portions of the internal electrodes.

9. The capacitor component of claim 8, wherein the external electrodes are connected to the internal electrodes via the exposed portions thereof.

10. The capacitor component of claim 1, wherein the reinforcing layer includes an electrical insulating material.

11. The capacitor component of claim 10, wherein the reinforcing layer and the dielectric layer include a same material.

12. The capacitor component of claim 11, wherein the reinforcing layer and the dielectric layer include a sintered ceramic.

13. The capacitor component of claim 1, wherein at least one external electrode has a multilayer structure.

14. The capacitor component of claim 13, wherein the at least one external electrode includes a first layer that is a sintered electrode and a second layer that covers the first layer and is a plating electrode.

15. A method of manufacturing a capacitor component, comprising:
forming a body by alternately stacking a plurality of dielectric layers and internal electrodes;
forming reinforcing layers on surfaces of the body from which the internal electrodes are exposed, and thereby covering portions of the internal electrodes; and
forming external electrodes connected to the internal electrodes and covering the reinforcing layers.

16. The method of claim 15, wherein the forming the reinforcing layers includes transferring the reinforcing layer to the body.

17. The method of claim 15, further comprising co-sintering the body and the reinforcing layers.
